(19) United States
(12) Patent Application Publication
(10) Pub. No.: US 2006/0196765 A1
(43) Pub. Date: Sep. 7, 2006

(54) Metallization target optimization method providing enhanced metallization layer uniformity

(75) Inventors: Hsi-Kuei Cheng, Hsinchu City (TW); Chieh-Tsao Wang, Jhubei City (TW); Hsien-Ping Feng, Yonghe City (TW); Min-Yuan Cheng, Taipei City (TW); Jung-Chin Tsao, Taipei (TW); Steven Lin, Shin-Chu (TW); Ray Chuang, Hsinchu City (TW); Chyi-Tsong NI, Hsinchu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 11/074,524

(22) Filed: Mar. 7, 2005

(51) Int. Cl. C23C 14/32; C23C 14/00

(52) U.S. Cl. 204/192.1; 204/192.15

(57) ABSTRACT

A method for forming a microelectronic layer while employing a sputtering method employs a reactor chamber. A sputtering target and a substrate are positioned within the reactor chamber, along with a sputtering target heater at a side of sputtering target opposite the substrate. At least one of: (1) a heater to sputtering target distance; (2) sputtering power; (3) deposition time; and (4) sputtering gas flow rate, is controlled in accord with a pre-determined function of sputtering target lifetime to provide enhanced uniformity of the deposited layer.

### BACKGROUND OF THE INVENTION

1. Field of the Invention

The invention relates generally to microelectronic products. More particularly, the invention relates to metallization methods and metallization apparatus within microelectronic products.

2. Description of the Related Art

Microelectronic products are fabricated from microelectronic substrates over which are formed patterned conductor layers that are separated by dielectric layers.

As microelectronic fabrication integration levels have increased and microelectronic device dimensions have decreased, the uniformity with which conductor layers are formed within microelectronic products has become increasingly important. Conductor layer uniformity is important since it directly influences electrical properties of microelectronic products.

Conductor layers may be deposited employing several methods within microelectronic products, including vacuum deposition methods such as sputtering methods. Vacuum deposition methods are desirable for forming conductor layers since they often provide conductor layers with desirable properties. However, forming uniform conductor layers within microelectronic products while employing vacuum deposition methods is not entirely without problems.

The invention is thus directed towards forming conductor layers within microelectronic products with enhanced uniformity.

### SUMMARY OF THE INVENTION

A first object of the invention is to provide a method for forming a conductor layer within a microelectronic product.

A second object of the invention is to provide a method in accord with the first object of the invention, wherein the conductor layer is formed with enhanced uniformity.

In accord with the objects of the invention, the invention provides a method for forming a microelectronic layer within a microelectronic product with enhanced uniformity.

To practice the method of the invention, a reactor chamber is provided. The reactor chamber has a substrate positioned therein opposite a sputtering target. The apparatus may also have a heater positioned on a side of the sputtering target opposite the substrate. Within the invention, a microelectronic layer is sputtered from the sputtering target onto the substrate while dynamically adjusting at least one of: (1) a distance of the heater from the sputtering target; (2) a power of the sputtering apparatus; (3) a deposition time; and (4) a sputtering gas flow rate. The adjustment is made within the context of a pre-determined correlation of the variable over the lifetime of the sputtering target, such as to optimize uniformity of the microelectronic layer.

The invention may be employed for forming conductor layers of various materials and thicknesses within microelectronic products.

The invention provides a method for forming a conductor layer within a microelectronic product with enhanced uniformity.

The invention realizes the foregoing object within the context of a sputtering method for forming the microelectronic layer. Within the sputtering method, at least one of: (1) a distance of a heater from a sputtering target; (2) a power of a sputtering apparatus; (3) a deposition time; and (4) a sputtering gas flow rate, is adjusted within the context of a pre-determined correlation of the variable over the lifetime of the sputtering target, such as to optimize uniformity of the microelectronic layer.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 shows a schematic diagram of a reactor apparatus in accord with a preferred embodiment of the invention.

FIG. 2 shows a graph of Percent Uniformity versus Heater to Target Spacing for a cobalt target in accord with a preferred embodiment of the invention.

FIG. 3 shows a graph of Spacing Distance versus Target Lifetime for a spaced target in accord with a preferred embodiment of the invention.

### DESCRIPTION OF THE PREFERRED EMBODIMENT

The invention provides a method for forming a microelectronic layer within a microelectronic product with enhanced uniformity.

The invention realizes the foregoing object within the context of a sputtering method for forming the microelectronic layer. Within the sputtering method, at least one of: (1) a distance of a heater from a sputtering target; (2) a power of a sputtering apparatus; (3) a deposition time; and (4) a sputtering gas flow rate, is adjusted within the context of a pre-determined correlation of the variable over the lifetime of the sputtering target, such as to optimize uniformity of the microelectronic layer.

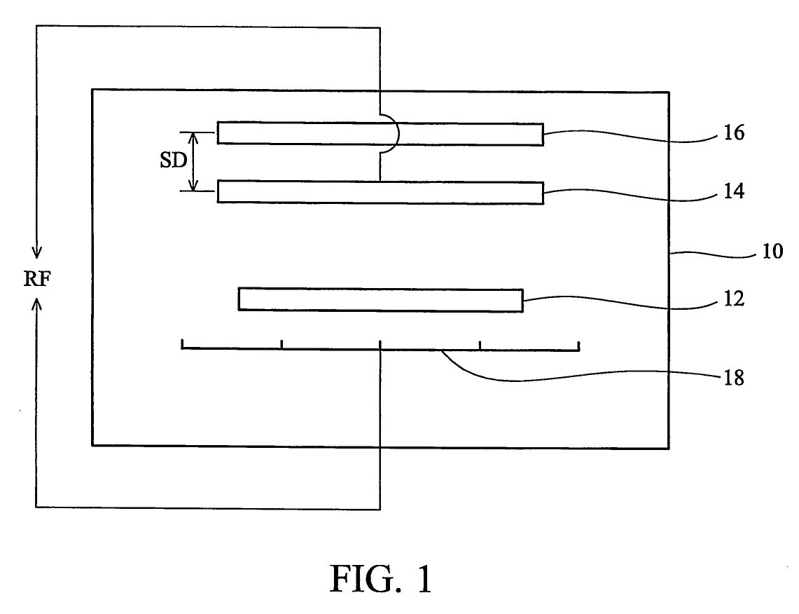

FIG. 1 shows a schematic diagram of a reactor apparatus in accord with the invention.

FIG. 1 shows a reactor chamber 10. The reactor chamber 10 is a sputtering reactor chamber. A substrate 12 is positioned within the reactor chamber 10 with respect to a sputtering target 14, and a heater 16 is positioned opposite the sputtering target 14 from the substrate 12. The reactor chamber 10 is typically maintained at a reactor chamber pressure of from about 1 to about 100 mtorr. Also, a sputtering gas is introduced into the reactor chamber 10 for purposes of sputtering a conductor layer from the sputtering target 14 while employing the sputtering apparatus. A radio frequency RF power powers the target 14 with respect to a radio frequency electrode 18.

The sputtering target 14 may be formed from materials including but not limited to conductor materials, semiconductor materials and dielectric materials. The sputtering target 14 may in particular be formed from any of several metals, including but not limited to tungsten, titanium, nickel and cobalt metals, as well as silicides thereof and nitrides thereof. Preferably, the sputtering target 14 is formed of cobalt. The heater 16 may be formed from any type of heater material as is conventional in the microelectronic fabrication art, including but not limited to metallic heater materials and ceramic heater materials. Typically, the heater 16 is formed employing a ceramic heater material.

The substrate 12 may be employed within a microelectronic product selected from the group including but not limited to integrated circuit products, ceramic substrate products and optoelectronic products.

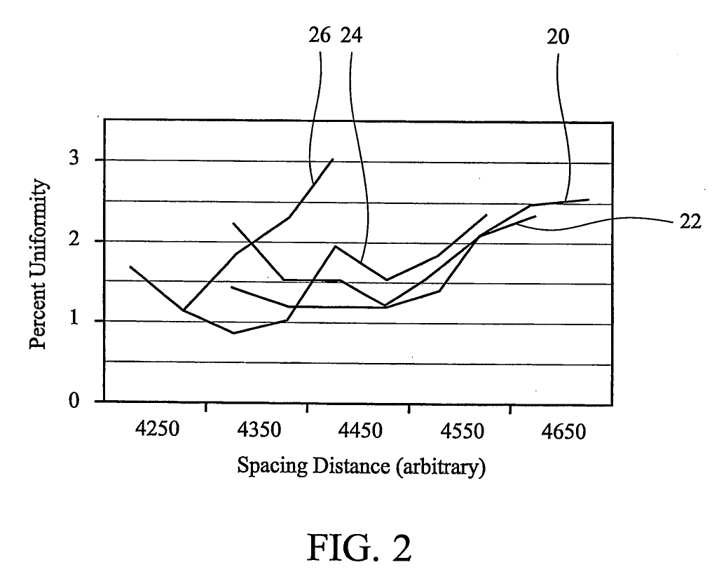

FIG. 2 shows a graph of percent uniformity versus spacing distance for a cobalt layer deposition in accord with the apparatus of FIG. 1. The curves that correspond with reference numerals 20, 22, 24 and 26 correspond with 3, 13, 23 and 33 kilowatt hours thermal load to the sputtering target which in turn corresponds generally with a use time of the sputtering target. As is illustrated in FIG. 2, cobalt layer uniformity is directly influenced by heater to target spacing within the context of any of the foregoing thermal loads.

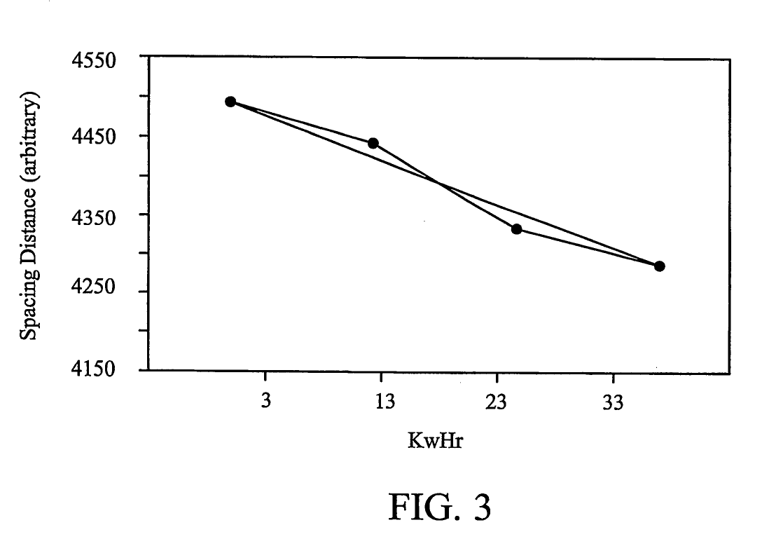

FIG. 3 further correlates heater to target spacing distance with heater output in terms of kilowatt hours (i.e., target use time). The data points fit a line defined by the equation:
Best Spacing Position=A[1−(1.55E−3*use time)]
where A varies from 3500 to 5500. Values of use time may be approximated as values of heater output, as above.

The foregoing equation may be employed for purposes of extrapolating a best spacing position for a heater with respect to a target in accord with the invention.

While the foregoing discussion has been presented within the context of a dynamic modification of a heater to target spacing predicated upon historic correlations to provide for enhanced uniformity when sputter depositing a microelectronic layer, the invention is not so limited. Rather, the invention may also be practiced within the context of historic determination of a radio frequency power over a lifetime of a sputtering target to dynamically provide enhanced uniformity, historic determination of deposition time over a lifetime of a sputtering target to dynamically provide enhanced uniformity of a deposited layer or historic determination of sputter gas flow rate (i.e., argon) over a lifetime of a sputtering target to dynamically provide enhanced uniformity of a deposited layer. Suitable historic data determinations, while not specifically illustrated within this disclosure, are deemed to be readily within the abilities of one skilled in the art.

FIGS. 1-3 show a schematic diagram and a pair of graphs of operation of an apparatus in accord with a preferred embodiment of the invention. The apparatus provides for optimization of a uniformity of a deposited microelectronic layer by dynamically adjusting at least one of a heater spacing, a power, a deposition time and a sputter gas flow rate in accord with an historic function of a target lifetime when depositing a metal layer while employing the deposition apparatus.

The preferred embodiment of the invention is illustrative of the invention rather than limiting of the invention. Revisions and modifications may be made to methods, materials, structures and dimensions in accord with the preferred embodiment of the invention while still providing an embodiment in accord with the invention, further in accord with the accompanying claims.

What is claimed is:

1. A method for forming a microelectronic layer comprising:
providing a reactor chamber;
positioning a substrate with respect to a front side of a sputtering target within the reactor chamber;
positioning a sputtering target heater with respect to a backside of the sputtering target; and
adjusting a separation distance of the sputtering target with respect to the heater such that a uniformity of a microelectronic layer sputtered from the sputtering target to the substrate is optimized.

2. The method of claim 1 wherein the separation distance of the sputtering target with respect to the heater is adjusted within the context of a pre-determined correlation of the variable over the lifetime of the sputtering target, such as to optimize uniformity of the microelectronic layer.

3. The method of claim 1 wherein the microelectronic layer is selected from the group consisting of conductor layers, semiconductor layers and dielectric layers.

4. The method of claim 1 wherein the reactor chamber is held at a pressure of from about 1 to about 100 mtorr.

5. The method of claim 1 wherein the substrate is selected from the group consisting of integrated circuit substrates, ceramic substrates and optoelectronic substrates.

6. The method of claim 1 wherein the sputtering target comprises a metal selected from the group consisting of tungsten, titanium, nickel and cobalt.

7. The method of claim 1 wherein the sputtering target comprises cobalt.

8. The method of claim 1 wherein the heater to target spacing is determined according to the equation:
Best Spacing Position=A[1−(1.55E−3*use time)]

9. A method for forming a microelectronic layer comprising:
providing a reactor chamber;
positioning a substrate with respect to a sputtering target within the reactor chamber; and
sputtering the sputtering target to form a microelectronic layer upon the substrate while adjusting a sputtering power with respect to an expected lifetime of the sputtering target, where the adjustment is made within the context of a pre-determined correlation of the variable over the lifetime of the sputtering target, such as to optimize uniformity of the microelectronic layer.

10. The method of claim 9 wherein the reactor chamber is held at a vacuum of from about 0.01 to about 0.001 torr.

11. The method of claim 9 wherein the substrate is selected from the group consisting of integrated circuit substrates, ceramic substrates and optoelectronic substrates.

12. The method of claim 9 wherein the sputtering target comprises a metal selected from the group consisting of copper, gold, tungsten, titanium and nickel.

13. A method for forming a microelectronic layer comprising:
providing a reactor chamber;
positioning a substrate with respect to a sputtering target within the reactor chamber; and
sputtering the sputtering target to form a conductor layer upon the substrate while adjusting a deposition time with respect to an expected lifetime of the sputtering target, where the adjustment is made within the context of a pre-determined correlation of the variable over the lifetime of the sputtering target, such as to optimize uniformity of the microelectronic layer.

14. The method of claim 13 wherein the reactor chamber is held at a vacuum of from about 0.01 to about 0.001 torr.

15. The method of claim 13 wherein the substrate is selected from the group consisting of integrated circuit substrates, ceramic substrates and optoelectronic substrates.

16. The method of claim 13 wherein the sputtering target comprises a metal selected from the group consisting of copper, gold, tungsten, titanium and nickel.

17. A method for forming a microelectronic layer comprising:
providing a reactor chamber;
positioning a substrate with respect to a sputtering target within the reactor chamber; and
sputtering the sputtering target to form a conductor layer upon the substrate while adjusting a sputtering gas flow with respect to an expected lifetime of the sputtering target, where the adjustment is made within the context of a pre-determined correlation of the variable over the lifetime of the sputtering target, such as to optimize uniformity of the microelectronic layer.

18. The method of claim 17 wherein the reactor chamber is held at a vacuum of from about 0.01 to about 0.001 torr.

19. The method of claim 17 wherein the substrate is selected from the group consisting of integrated circuit substrates, ceramic substrates and optoelectronic substrates.

20. The method of claim 17 wherein the sputtering target comprises a metal selected from the group consisting of copper, gold, tungsten, titanium and nickel.
